(19) United States
(12) Patent Application Publication
(10) Pub. No.: US 2026/0114269 A1
(43) Pub. Date: Apr. 23, 2026

(54) ENHANCED THERMAL DISSIPATION FOR BACKSIDE POWER DISTRIBUTION NETWORK

(71) Applicant: QUALCOMM Incorporated, San Diego, CA (US)

(72) Inventors: Abhishek JAIN, San Diego, CA (US); Junjing BAO, San Diego, CA (US); John Jianhong ZHU, San Diego, CA (US); Giridhar NALLAPATI, San Diego, CA (US)

(21) Appl. No.: 18/924,402

(22) Filed: Oct. 23, 2024

(51) Int. Cl. H01L 23/532; H01L 21/768; H01L 23/373; H01L 23/528; H01L 27/088; H01L 29/06; H01L 29/423; H01L 29/775; H01L 29/78; H01L 29/786

(52) U.S. Cl. CPC H10W 20/48; H10D 84/83; H10W 20/435; H10W 40/253; H10D 30/43; H10D 30/62; H10D 30/6735; H10D 30/6757; H10D 62/121; H10W 20/023

(57) ABSTRACT

A chip includes an active device, a first backside silicon layer disposed below the active device, a first backside metal path electrically coupled to the active device and extending through the first backside silicon layer, and a first electrical barrier disposed between one or more sides of the first backside metal path and the first backside silicon layer.

### BACKGROUND

### Field

Aspects of the present disclosure relate generally to semiconductors, and more particularly, to thermal dissipation in a chip.

### Background

A chip includes many active devices for performing various functions on the chip. The active devices may be implemented using gate-all-around field effect transistors (GAAFETs), fin field effect transistors (FinFETs), and/or other types of transistors. The chip may also include backside metal layers under the active devices. The backside metal layers may be patterned to provide a backside power distribution network (BSPDN) for delivering power to the active devices.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a chip. The chip includes an active device, a first backside silicon layer disposed below the active device, a first backside metal path electrically coupled to the active device and extending through the first backside silicon layer, and a first electrical barrier disposed between one or more sides of the first backside metal path and the first backside silicon layer.

A second aspect relates to a chip. The chip includes active devices, one or more backside silicon layers disposed below the active devices, and a backside power distribution network extending through the one or more backside silicon layers, wherein the backside power distribution network is configured to provide the active devices with a supply voltage.

### BRIEF DESCRIPTION OF THE DRAWINGS

FIG. 1A shows a side view of an example of a chip including active devices and frontside layers according to certain aspects of the present disclosure.

FIG. 1B shows a side view of another example of a chip including active devices and frontside layers according to certain aspects of the present disclosure.

FIG. 2A shows a side view of an example of a chip including active devices, frontside layers, and backside layers according to certain aspects of the present disclosure.

FIG. 2B shows a side view of another example of a chip including active devices, frontside layers, and backside layers according to certain aspects of the present disclosure.

FIG. 3A shows an example of a chip after frontside processing according to certain aspects of the present disclosure.

FIG. 3B shows an example in which the chip of FIG. 3A is flipped over according to certain aspects of the present disclosure.

FIG. 3C shows an example in which a silicon substrate of the chip is removed according to certain aspects of the present disclosure.

FIG. 3D shows an example in which an etch stop layer and a backside interlayer dielectric (BS-ILD) are deposited on the backside of the chip according to certain aspects of the present disclosure.

FIG. 3E shows an example in which trenches are etched into the BS-ILD according to certain aspects of the present disclosure.

FIG. 3F shows an example in which metal is deposited into the trenches to form backside metal routing according to certain aspects of the present disclosure.

FIG. 3G shows an example in which the processes illustrated in FIGS. 3D to 3F are repeated to form an additional layer of backside metal routing according to certain aspects of the present disclosure.

FIG. 4A shows a side view of an example of a chip including active devices, frontside layers, and backside layers where the backside layers include silicon layers to enhance thermal dissipation according to certain aspects of the present disclosure.

FIG. 4B shows a side view of another example of a chip including active devices, frontside layers, and backside layers where the backside layers include silicon layers to enhance thermal dissipation according to certain aspects of the present disclosure.

FIG. 5A shows an example of a chip after frontside processing according to certain aspects of the present disclosure.

FIG. 5B shows an example in which the chip of FIG. 5A is flipped over according to certain aspects of the present disclosure.

FIG. 5C shows an example in which a silicon substrate of the chip is removed according to certain aspects of the present disclosure.

FIG. 5D shows an example in which an etch stop layer and a backside silicon layer are deposited on the backside of the chip according to certain aspects of the present disclosure.

FIG. 5E shows an example in which trenches are etched into the backside silicon layer according to certain aspects of the present disclosure.

FIG. 5F shows an example in which an electrical barrier is formed in the trenches according to certain aspects of the present disclosure.

FIG. 5G shows an example in which portions of the electrical barrier are etched using a directional etch process and holes are etched through the etch stop layer according to certain aspects of the present disclosure.

FIG. 5H shows an example of deposition of electrical barrier material according to certain aspects of the present disclosure.

FIG. 5I shows an example in which metal is deposited into the trenches to form backside metal routing according to certain aspects of the present disclosure.

FIG. 5J shows an example in which the processes illustrated in FIGS. 5D to 5I are repeated to form an additional layer of backside metal routing according to certain aspects of the present disclosure.

FIG. 6A shows a perspective view of an example of active devices according to certain aspects of the present disclosure.

FIG. 6B shows the perspective view of FIG. 6A in which a gate in FIG. 6A is shown in phantom according to certain aspects of the present disclosure.

FIG. 7 shows a perspective view of another example of active devices according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

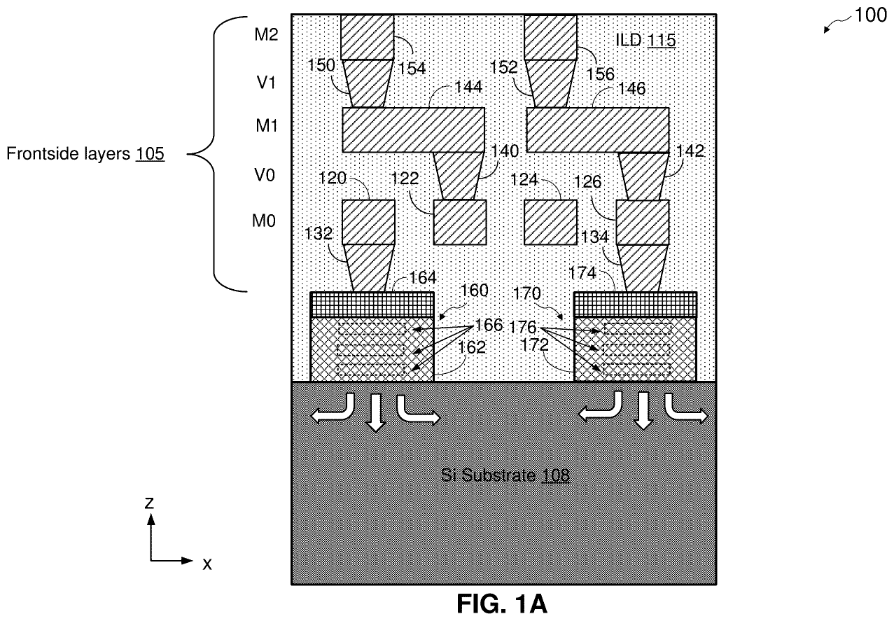

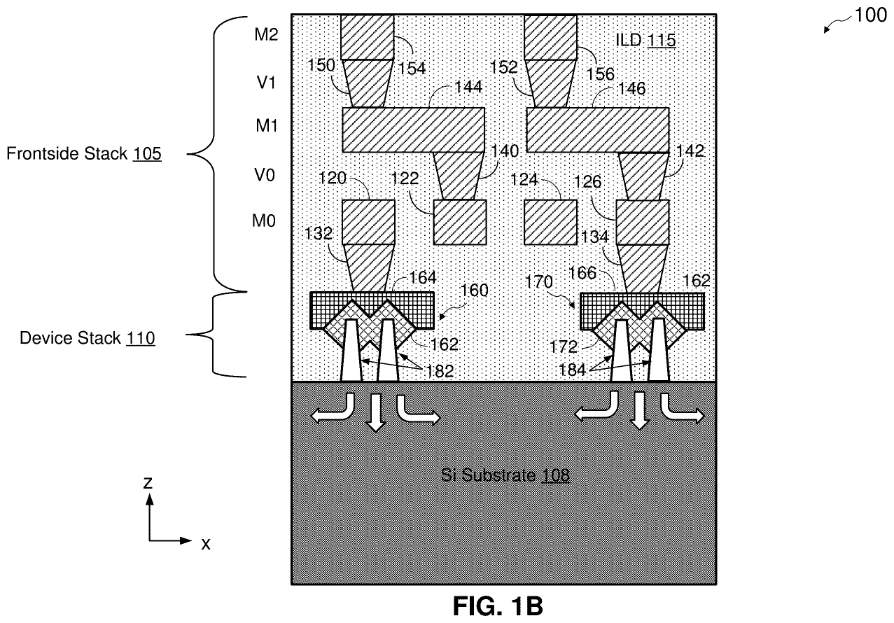

FIG. 1A shows a side view of an example of a chip 100 (e.g., a die) including active devices 160 and 170 and multiple frontside layers 105 (also referred to as the back end of line (BEOL)) according to certain aspects. As discussed further below, the active devices 160 and 170 may be implemented using a gate-all-around field effect transistor (FET) process, a fin field-effect transistor (FinFET) process, or another type of process. The frontside layers 105 are above active devices 160 and 170 in the z direction shown in FIG. 1A. The active devices 160 and 170 and the frontside layers 105 may be formed on a silicon substrate 108.

In the example shown in FIG. 1A, the active devices 160 and 170 are implemented using a gate-all-around FET process. An example in which the active devices 160 and 170 are implemented using a FinFET process is discussed later with reference to FIG. 1B.

In the example shown in FIG. 1A, the active device 160 includes an active region including one or more nanosheets 166 stacked in the z direction and an epitaxial (epi) layer 162 coupled to the one or more nanosheets 166. The epi layer 162 may provide a source/drain of the active device 160, and the one or more nanosheets 166 may pass through a gate (not shown in FIG. 1A) of the active device 160 to provide one or more channels of the active device 160. As used herein, a “source/drain” refers to a source, a drain, or both. The chip 100 may also include a frontside contact 164 disposed on the epi layer 162 to provide a source/drain contact for the active device 160.

In this example, the active device 170 includes an active region including one or more nanosheets 176 stacked in the z direction and an epi layer 172 coupled to the one or more nanosheets 176. The epi layer 172 may provide a source/drain of the active device 170, and the one or more nanosheets 176 may pass through a gate (not shown in FIG. 1A) of the active device 170 to provide one or more channels of the active device 170. The chip 100 may also include a frontside contact 174 disposed on the epi layer 172 to provide a source/drain contact for the active device 170.

Each of the epi layers 162 and 172 may include epitaxially grown or deposited silicon, a silicon-based material (e.g., silicon-germanium), or any combination thereof. Each of the one or more nanosheets may include silicon (e.g., deposited silicon) and/or another material.

In the example shown in FIG. 1A, the frontside layers 105 include metal layers M0, M1, and M2 (also referred to as metal interconnects or another term). The metal layers M0, M1, and M2 may be patterned (e.g., using lithography and etching) to provide signal routing for the active devices 160 and 170 and other active devices (not shown in FIG. 1A) integrated on the chip 100. The metal layers M0, M1, and M2 may also be patterned to form a power distribution network (PDN) including supply rails for distributing power to the active devices 160 and 170 and other active devices integrated on the chip 100.

In the example shown in FIG. 1A, the metal layer M0 is the bottom-most metal layer in the metal stack, the metal layer M1 is above the metal layer M0, and the metal layer M2 is above the metal layer M1. Although three metal layers (i.e., M0, M1, and M2) are shown in FIG. 1A, it is to be appreciated that the frontside layers 105 may include one or more additional metal layers above the metal layer M2. It is to be appreciated that the present disclosure is not limited to the nomenclature in which the bottom-most metal layer is referred to as metal layer M0. For instance, in another example, the bottom-most metal layer may be referred to as metal layer M1 instead of metal layer M0. Also, it is to be appreciated that one or more of the metal layers may be designated with a letter other than M in other examples. Accordingly, it is to be appreciated that the metal layers are not limited to the exemplary designations used in FIG. 1A. The chip 100 may also include an interlayer dielectric (ILD) 115 to provide electrical isolation between the metal layers. The ILD 115 may include silicon oxide and/or another dielectric material.

In the example shown in FIG. 1A, the metal layer M0 is patterned to form metal paths 120, 122, 124, and 126, the metal layer M1 is patterned to form metal paths 144 and 146, and the metal layer M2 is patterned to form metal paths 154 and 156. The metal paths 120, 122, 124, and 126 in the metal layer M0 may extend in the y direction, the metal paths 144 and 146 in the metal layer M1 may extend in the x direction, and the metal paths 154 and 156 in the metal layer M2 may extend in the y direction. It is to be appreciated that the present disclosure is not limited to the exemplary metal routing shown in FIG. 1A.

In the example shown in FIG. 1A, the frontside layers 105 includes vias V0 and vias V1, in which the vias V0 provide coupling between the metal layer M0 and the metal layer M1 and the vias V1 provide coupling between the metal layer M1 and the metal layer M2. In the example in FIG. 1A, the vias V0 include a via 140 coupling the metal path 122 and the metal path 144 and a vias 142 coupling the metal path 126 and the metal path 146. The vias V1 include a via 150 coupling the metal path 144 and the metal path 154 and a via 152 coupling the metal path 146 and the metal path 156.

In the example shown in FIG. 1A, the frontside layers 105 also includes a via 132 coupling the frontside contact 164 with the metal path 120 in the metal layer M0 and a via 134 coupling the frontside contact 174 with the metal path 126. It is to be appreciated that the present disclosure is not limited to the exemplary vias shown in FIG. 1A.

FIG. 1B shows an example in which the active devices 160 and 170 are implemented using a FinFET process. In this example, the active region of the active device 160 includes one or more fins 182 with the epi layer 162 coupled to the one or more fins 182. The one or more fins 182 are orientated vertically and are spaced apart from one another in the horizontal direction (x direction in FIG. 1B). The epi layer 162 and/or the one or more fins 182 may provide the source/drain of the active device 160. The one or more fins 182 may also pass through the gate (not shown in FIG. 1A) of the active device 160 to provide the one or more channels of the active device 160. In this example, each fin may be surrounded on three sides by the gate.

In the example shown in FIG. 1B, the active region of the active device 170 includes one or more fins 184 with the epi layer 172 coupled to the one or more fins 184. The one or more fins 184 are orientated vertically and are spaced apart from one another in the horizontal direction (x direction in FIG. 1B). The epi layer 172 and/or the one or more fins 184 may provide the source/drain of the active device 170. The one or more fins 184 may also pass through the gate (not shown in FIG. 1B) of the active device 170 to provide the one or more channels of the active device 170.

The fins 182 and 184 may include silicon or another material. For example, in some implementations, the fins 182 and 184 may be fabricated by etching a top portion of the silicon substrate 108 to form the fins 182 and 184. However, it is to be appreciated that the present disclosure is not limited to this example.

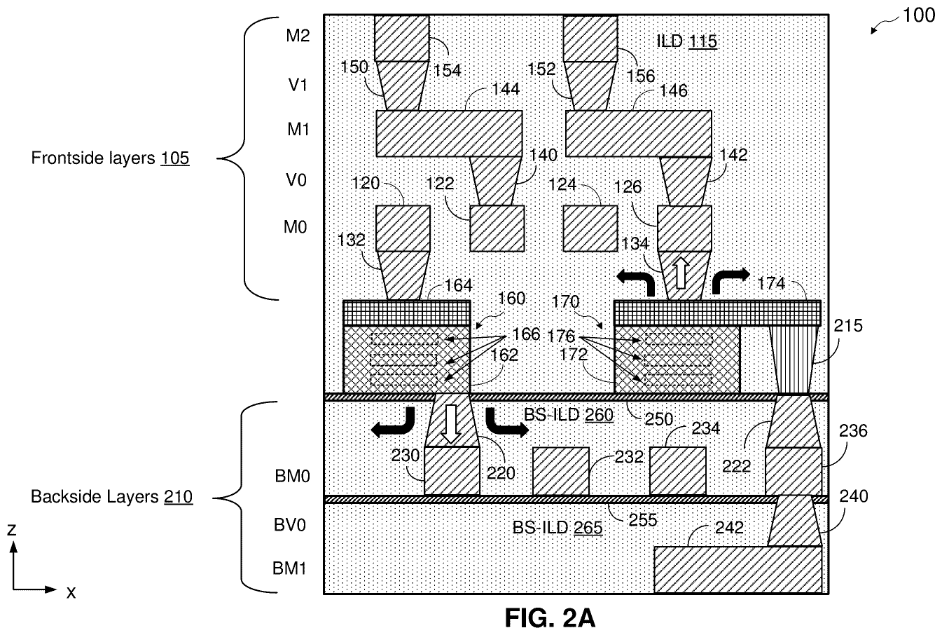

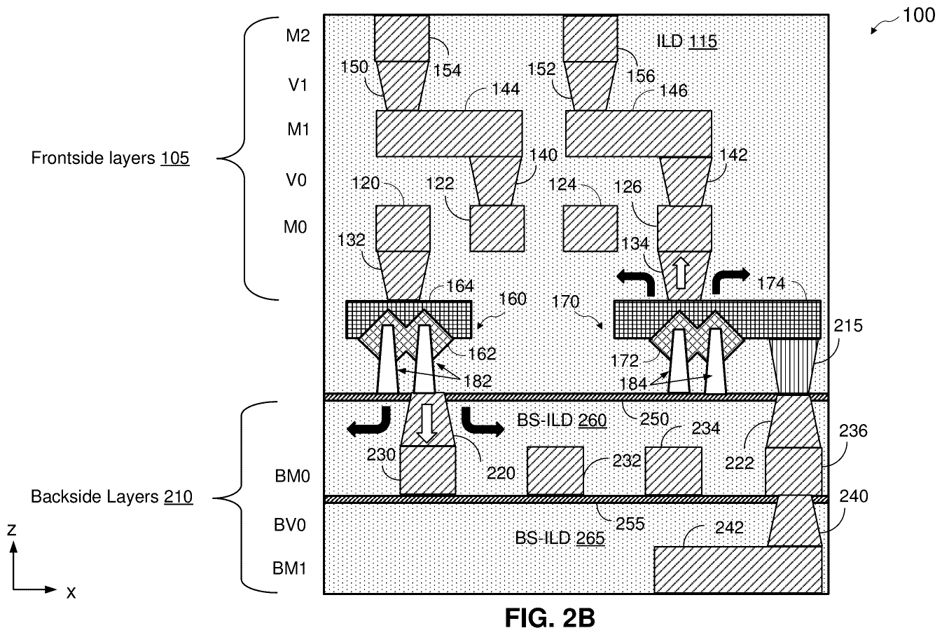

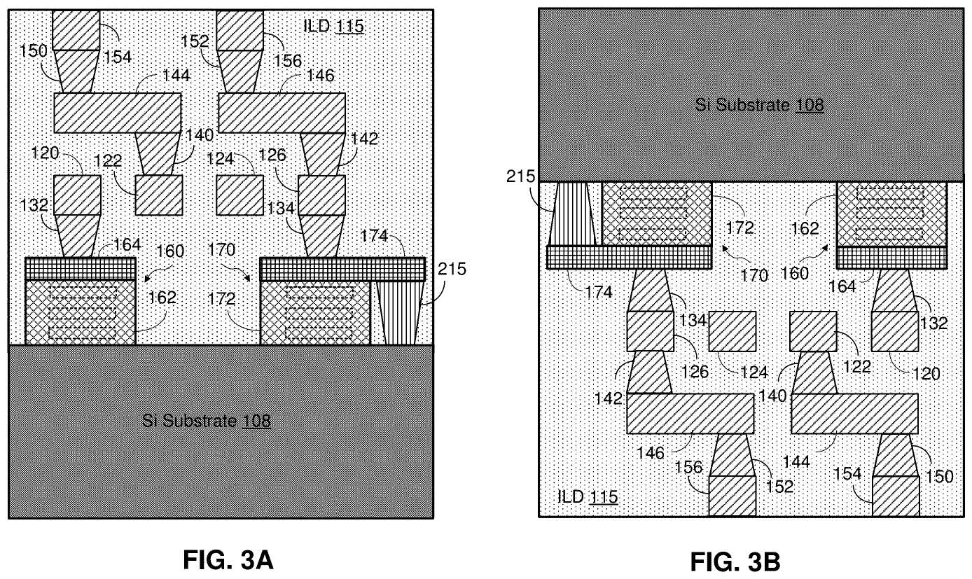

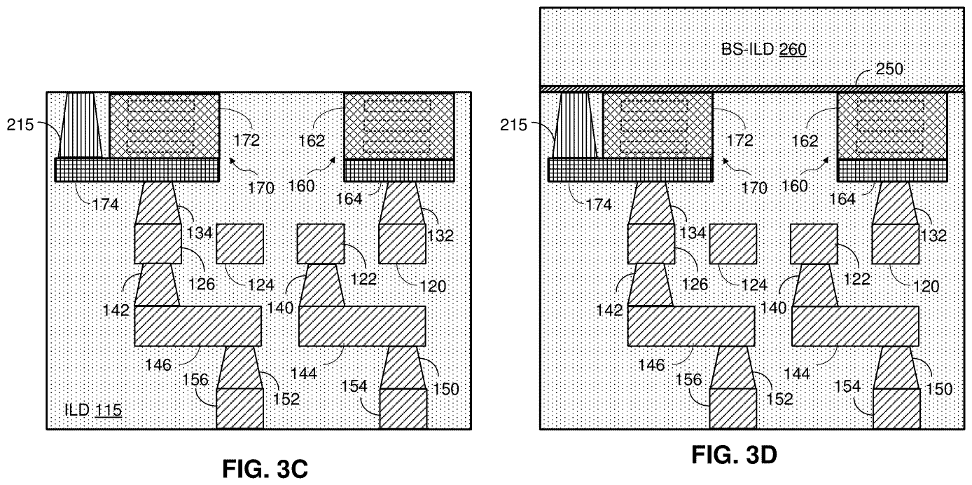

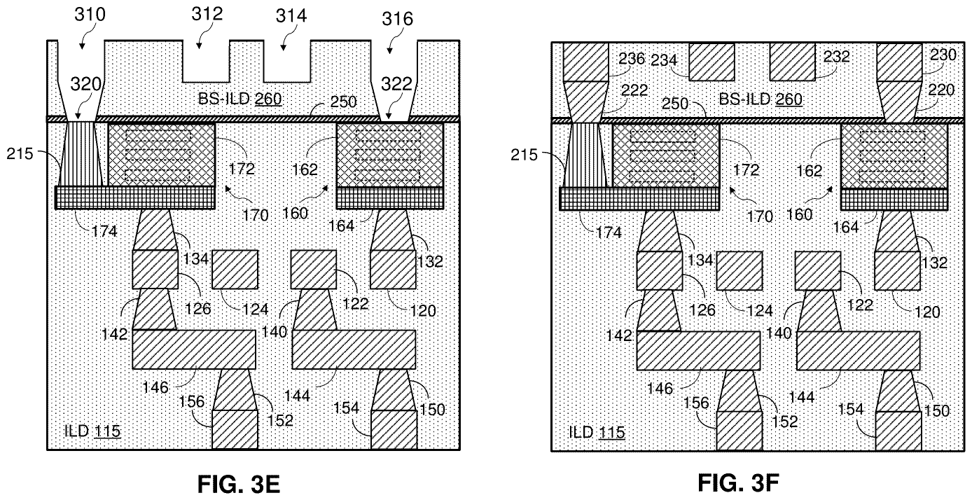

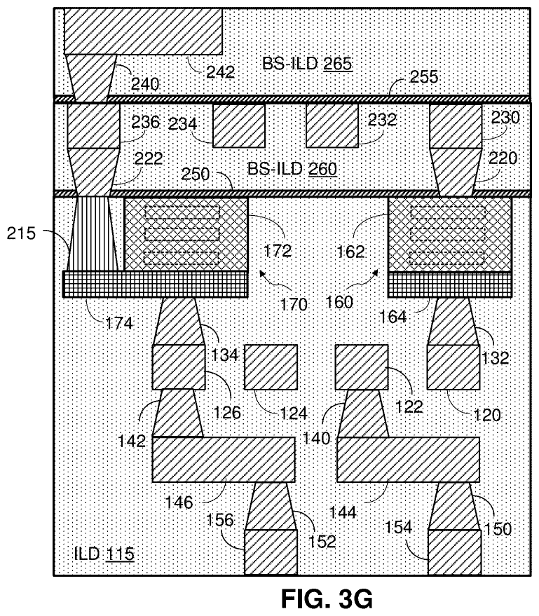

FIG. 2A shows an example in which the chip 100 includes backside layers 210 to facilitate backside routing. In this example, most or all of the silicon substrate 108 (not shown in FIG. 2A) may be removed to form backside layers 210 under the active devices 160 and 170. An exemplary backside process for forming the backside layers 210 is discussed further below with reference to FIGS. 3A to 3G. In the example shown in FIG. 2A, the active devices 160 and 170 are implemented with the gate-all-around FET process discussed above with reference to FIG. 1A.

In the example in FIG. 2A, the backside layers 210 include backside metal layers BM0 and BM1. The metal layers BM0 and BM1 may also be patterned (e.g., using lithography and etching) to form a backside power distribution network (BSPDN) including supply rails for distributing power to the active devices 160 and 170 and other active devices integrated on the chip 100.

In the example in FIG. 2A, the backside metal layer BM0 is the top-most metal layer in the backside metal stack, and the backside metal layer BM1 is below the backside metal layer BM0. Although two backside metal layers (i.e., BM0 and BM1) are shown in FIG. 2A, it is to be appreciated that the backside layers 210 may include one or more additional backside metal layers below the backside metal layer BM1. It is to be appreciated that the backside metal layers are not limited to the exemplary designations used in FIG. 2A.

In the example shown in FIG. 2A, the backside metal layer BM0 is patterned to form backside metal paths 230, 232, 234, and 236 and the backside metal layer BM1 is patterned to form backside metal path 242. The backside metal paths 230, 232, 234, and 236 in the backside metal layer BM0 may extend in the y direction to provide power routing in the y direction and the backside metal path 242 in backside metal layer BM1 may extend in the x direction to provide power routing in the x direction. In the example shown in FIG. 2A, the metal paths 232 and 234 may be coupled to and provide power routing for other active devices (not shown) on the chip 100. Also, the metal path 230 may be coupled to a metal path (not shown) in the backside metal layer BM1. It is to be appreciated that the present disclosure is not limited to the exemplary metal routing shown in FIG. 2A.

In the example shown in FIG. 2A, the backside layers 210 includes backside vias BV0 which provide coupling between the backside metal layer BM0 and the backside metal layer BM1. In this example, the backside vias BV0 include backside via 240 coupling the backside metal path 236 and the backside metal path 242.

In the example shown in FIG. 2A, the backside layers 210 also includes a via 220 coupling the source/drain (e.g., the epi layer 162) of the active device 160 with the metal path 230 in the backside metal layer BM0. In this example, the backside layers 210 also include a via 222 coupling the source/drain (e.g., the epi layer 172) of the active device 170 with the metal path 236 in the backside metal layer BM0. In the example shown in FIG. 2A, the via 222 is coupled to the epi layer 172 through the frontside contact 174 and a via 215 coupled between the frontside contact 174 and the via 222. In other implementations, the vias 222 may be coupled to the backside (i.e., bottom) surface of the epi layer 172 with the via 215 omitted. It is to be appreciated that the present disclosure is not limited to the exemplary vias shown in FIG. 2A.

In the example shown in FIG. 2A, the chip 100 may also include a first backside interlayer dielectric (BS-ILD) 260 and a second BS-ILD 265 below the first BS-ILD 260. The chip 100 also includes a first etch stop layer 250 between the active devices 160 and 170 and the first BS-ILD 260 and a second etch stop layer 255 between the first BS-ILD 260 and the second BS-ILD 265. As discussed further below, the etch stop layers 250 and 255 are used as etch stops for the first BS-ILD 260 and the second BS-ILD 265, respectively, during backside process. In some implementations, the first BS-ILD 260 and the second BS-ILD 265 includes silicon oxide and/or another dielectric. In these implementations, the etch stop layers 250 and 255 may include silicon nitride or another material that can be used as a suitable etch stop for the first BS-ILD 260 and the second BS-ILD 265.

FIG. 2B shows an example of the backside layers 210 for the example where the active devices 160 and 170 are implemented using the FinFET process discussed above with reference to FIG. 1B. In this example, the vias 220 may be coupled to the one or more fins 182 either directly or through a backside contact (not shown) disposed between the one or more fins 182 and the vias 220. In the example shown in FIG. 2B, the via 222 is coupled to the one or more fins 184 through the frontside contact 174 and the via 215 coupled between the frontside contact 174 and the via 222. In other implementations, the vias 222 may be coupled to the one or more fins 184 from the backside either directly or through a backside contact (not shown). It is to be appreciated that the present disclosure is not limited to the example shown in FIG. 2B.

In certain aspects, the frontside layers 105 are patterned to provide signal routing for the active devices 160 and 170 and other active devices (not shown) integrated on the chip 100. The backside layers 210 are patterned to form a backside power distribution network (BSPDN) to provide power to the active devices 160 and 170 and the other active devices from the backside. Moving the power distribution to the backside layers 210 helps reduce routing congestion compared with the case where the frontside layers 105 are used for both signal routing and power distribution. The reduced routing congestion allows the metal paths (also referred to as metal wires) of the BSPDN to be made wider, which reduces resistances (and hence IR drops) in the BSPDN.

FIGS. 3A to 3G illustrate an exemplary backside process for forming the backside layers 210 according to certain aspects. The exemplary backside process is shown for the example where the active devices 160 and 170 are implemented using the gate-all-around FET process. However, it is to be appreciated that the exemplary backside process is also applicable to the case where the active devices 160 and 170 are implemented using the FinFET process.

FIG. 3A shows an example of the chip 100 after formation of the active devices 160 and 170, the via 215, and the frontside layers 105 during frontside processing. In this example, the active devices 160 and 170 and the frontside layers 105 are fabricated on the silicon substrate 108.

After formation of the active devices 160 and 170 and the frontside layers 105, a carrier substrate may be bonded to the top of the chip 100 for structural support. The chip 100 may then be flipped to expose the backside of the silicon substrate 108, as shown in FIG. 3B. Note that the carrier substrate is not shown in FIG. 3B for ease of illustration.

In FIG. 3C, most or all of the silicon substrate 108 is removed to expose the backside of the active devices 160 and 170. For example, the silicon substrate 108 may be grounded and/or polished off (e.g., using chemical mechanical polishing (CMP)).

In FIG. 3D, the first etch stop layer 250 and the first BS-ILD 260 (e.g., silicon oxide) are deposited on the backside of the chip 100.

In FIG. 3E, the first BS-ILD 260 is etched to form trenches 310, 312, 314, and 316 for the vias 220 and 222 and the metal paths 230, 232, 234, and 236 in the metal layer M0 (shown in FIGS. 2A and 2B). The areas of the first BS-ILD 260 that are etched to form the trenches 310, 312, 314, and 316 may be defined using lithography. In this example, the first etch stop layer 250 acts as an etch stop for the etching process used to etch the first BS-ILD 260 (i.e., the etch selectivity for the first BS-ILD 260 is high in relation to the etch stop layer 250).

After the etching of the first BS-ILD 260, holes 320 and 322 (i.e., openings) are etched through the etch stop layer 250 to expose the backsides of the active devices 160 and 170. In the example shown in FIG. 3E, the hole 322 exposes the backside of the source/drain (e.g., the epi layer 162) of the active device 160. In some implementations, the via 215 may be omitted and the hole 320 may expose the backside of the source/drain (e.g., the epi layer 172) of the active device 170.

FIG. 3F illustrates a backside metallization process in which metal is deposited in the trenches 310, 312, 314, and 316 and the holes 320 and 322 to form the vias 220 and 222 and the metal paths 230, 232, 234, and 236 in the backside metal layer BM0. The metal may include one or more different types of metal.

FIG. 3G shows an example in which the deposition, etching, and metallization processes illustrated in FIGS. 3D to 3F are repeated to form the second BS-ILD 265, the via 240, and the metal path 242 in the backside metal layer BM1.

During operation, the active devices 160 and 170 generate heat which needs to be dissipated to prevent overheating the chip 100. The heat generation increases as the active devices 160 and 170 operate at higher speeds. Overheating may cause damage to the active devices 160 and 170 and/or cause a temperature management circuit to shut down the active devices 160 and 170 or significantly reduce the speed of the active devices 160 and 170 to prevent damage.

For the case of frontside power distribution illustrated in FIGS. 1A and 1B, the silicon substrate 108 provides a good thermal conductor as well as a heat sink for dissipating heat from the active devices 160 and 170. FIGS. 1A and 1B show arrows indicating the heat flow from the active devices 160 and 170 to the silicon substrate 108.

For the case of backside power distribution illustrated in FIGS. 2A and 2B, the chip 100 may include several microns of dielectric layers (e.g., ILD and BS-ILD) on both the top and the bottom of the active devices 160 and 170. The dielectric layers provide poor thermal conduction in all directions compared with the silicon substrate 108 in FIGS. 1A and 1B. For example, for an oxide-based dielectric, the silicon substrate 108 may have a thermal conductivity that is 10 or more times higher than the thermal conductivity of the dielectric layers. In FIGS. 2A and 2B, the dark arrows indicate poor thermal conduction compared with the white arrows. Note that the lateral heat conduction paths from the active device 160 indicated by the arrows in FIGS. 2A and 2B also apply to the active device 170.

As shown in FIGS. 2A and 2B, the lateral heat diffusion in the backside dielectric layers (e.g., the BS-ILDs 260 and 265) is poor. Since device hotspots are sensitive to lateral heat diffusion, the poor heat diffusion in the backside dielectric layers may cause the hot-spot temperatures of the active devices 160 and 170 to be significantly higher (e.g., 20 degrees higher) compared with the case where the chip 100 includes the silicon substrate 108 shown in FIGS. 1A and 1B.

To address the above, aspects of the present disclosure replace the backside dielectric layers (e.g., the BS-ILDs 260 and 265) with backside silicon layers. Since silicon has a much higher thermal conductivity (e.g., 10 times or more higher) than an oxide-based dielectric, the backside silicon layers improve lateral heat diffusion and lower hotspot temperatures while retaining the benefits of backside power distribution.

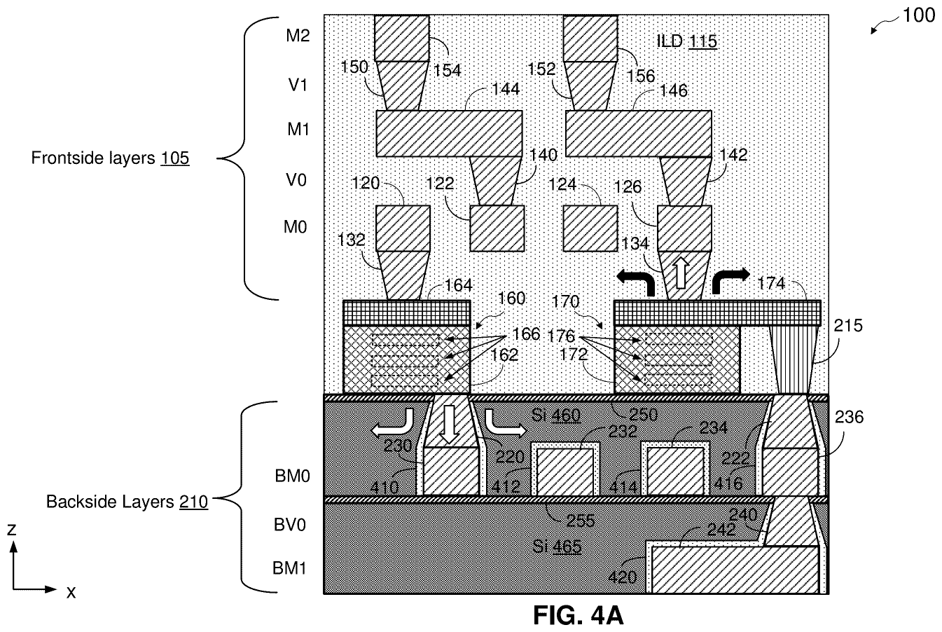

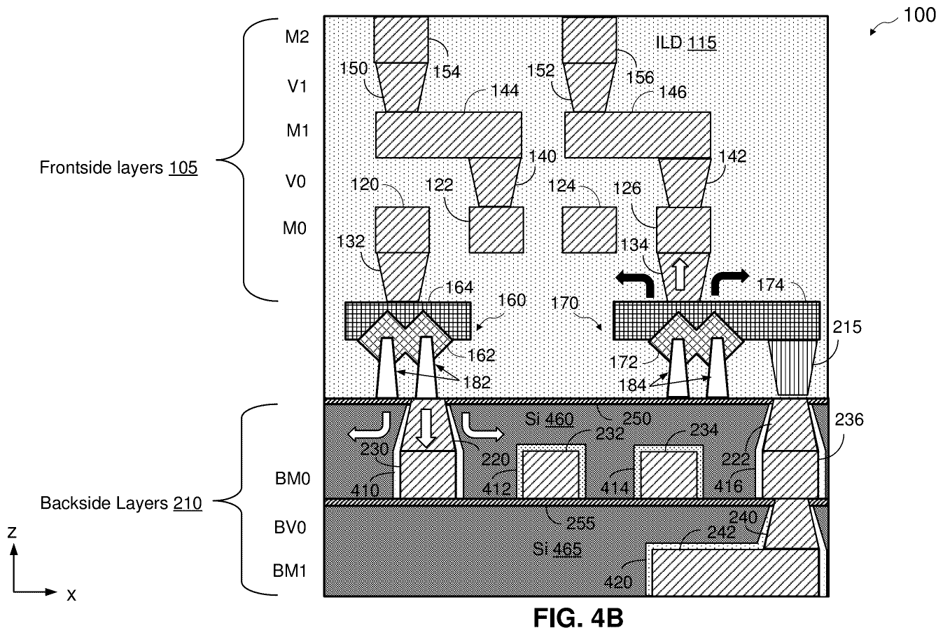

FIGS. 4A and 4B shows examples in which the backside layers 210 include a first backside silicon layer 460 and a second backside silicon layer 465 in place of the first BS-ILD 260 and the second BS-ILD 265 shown in FIGS. 2A and 2B. In FIG. 4A, the active devices 160 and 170 are implemented using the gate-all-around FET process discussed above, and, in FIG. 4B, the active devices 160 and 170 are implemented using the FinFET process discussed above. As indicated by the white arrows in FIGS. 4A and 4B, the backside silicon layers 460 and 465 provide good lateral heat diffusion compared with the backside dielectric layers (e.g., the BS-ILDs 260 and 265) in FIGS. 2A and 2B due to the much higher thermal conductivity of silicon. As discussed further below, the backside silicon layers 460 and 465 may be implemented with deposited silicon and/or epitaxial silicon.

In the examples shown in FIG. 4A and FIG. 4B, the first etch stop layer 250 is disposed between the active devices 160 and 170 and the first backside silicon layer 460 and the second etch stop layer 255 is disposed between the first backside silicon layer 460 and the second backside silicon layer 465. The etch stop layers 250 and 255 may include any material that can be used as a suitable etch stop for the first backside silicon layer 460 and the second backside silicon layer 465. Examples of materials that may be used for the etch stop layers 250 and 255 include silicon nitride (SiN), aluminum nitride (AlN), or any combination thereof.

In the examples shown in FIGS. 4A and 4B, the vias 220 and 222 and the metal paths 230, 232, 234, and 236 extend through the first backside silicon layer 460, and the via 240 and the metal path 242 extend through the second backside silicon layer 465, in which the backside silicon layers 460 and 465 provide good lateral heat diffusion for the vias 220, 222, and 240 and the metal paths 230, 232, 234, 236, and 242.

In the examples shown in FIGS. 4A and 4B, the backside layers 210 also include thin electrical barriers (e.g., oxide barriers, tantalum nitride (TaN) barriers, or any combination thereof) between the backside metal routing (e.g., the backside metal paths 230, 232, 234, 236, and 242 and the backside vias 220, 222, and 240) and the backside silicon layers 460 and 465. The electrical barriers help provide electrical isolation between the backside metal routing and the backside silicon layers 460 and 465. As used herein, an electrical barrier is a barrier having a low electrical conductivity compared with silicon.

In the examples shown in FIGS. 4A and 4B, the electrical barriers include electrical barriers 410, 412, 414, 416, and 420. The electrical barrier 410 is disposed between one or more sides of the metal path 230 and the first backside silicon layer 460 and between one or more sides of the via 220 and the first backside silicon layer 460. The electrical barrier 412 is disposed between one or more sides of the metal path 232 and the first backside silicon layer 460 and the electrical barrier 414 is disposed between the one or more sides of the metal path 234 and the first backside silicon layer 460. The electrical barrier 416 is disposed between the one or more sides of the metal path 236 and the first backside silicon layer 460 and between the one or more sides of the via 222 and the first backside silicon layer 460. The electrical barrier 420 is disposed between one or more sides of the metal path 242 and the second backside silicon layer 465 and between one or more sides of the via 240 and the second backside silicon layer 465.

In some examples, the electrical barriers may include a material (e.g., oxide) having poor thermal conductivity. However, the electrical barriers may be very thin compared with the backside silicon layers 460 and 465, and therefore have little impact on the high lateral heat diffusion provided by backside silicon layers 460 and 465. For example, the thickness of the electrical barriers may be 3 nm or more.

In the examples shown in FIGS. 4A and 4B, the backside layers 210 may be patterned to form the BSPDN to provide power to the active devices 160 and 170 and the other active devices from the backside. As discussed above, the BSPDN reduces routing congestion compared with frontside power distribution. In these examples, the backside silicon layers 460 and 465 allow the chip 100 to use backside power distribution while providing much higher backside heat dissipation compared with the backside dielectric layers shown in FIGS. 2A and 2B.

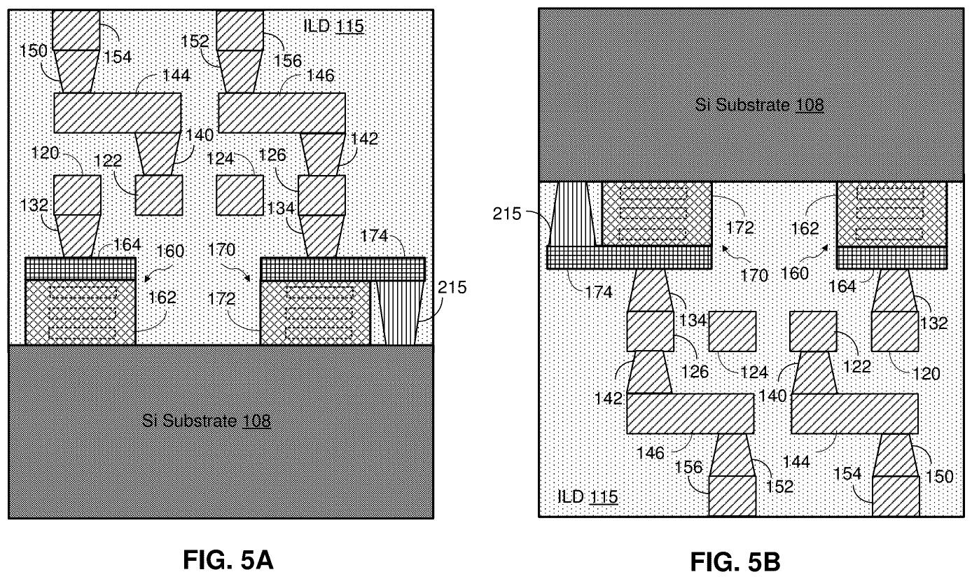

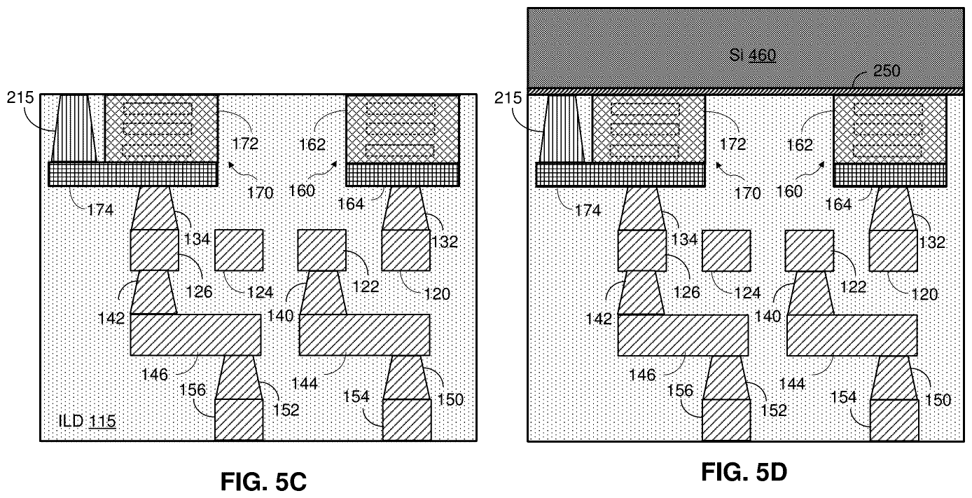

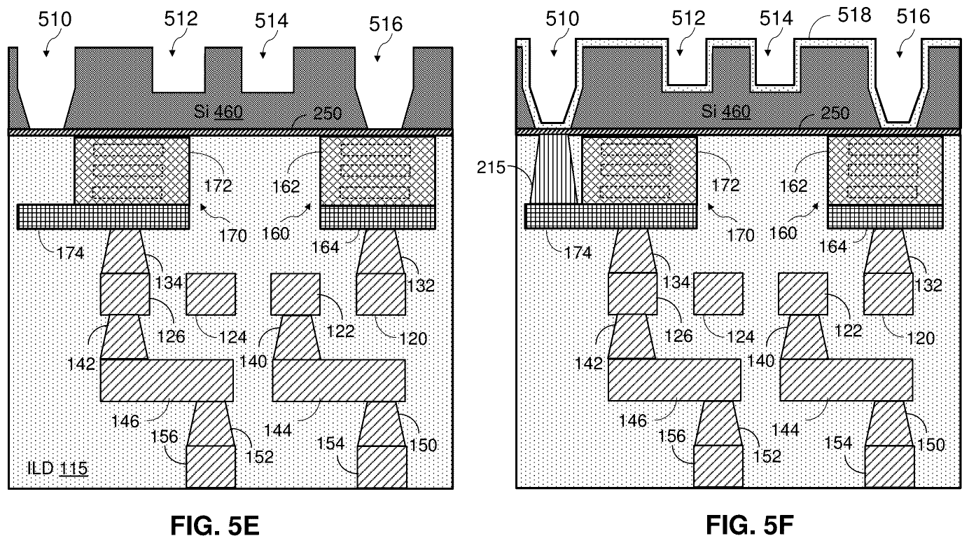

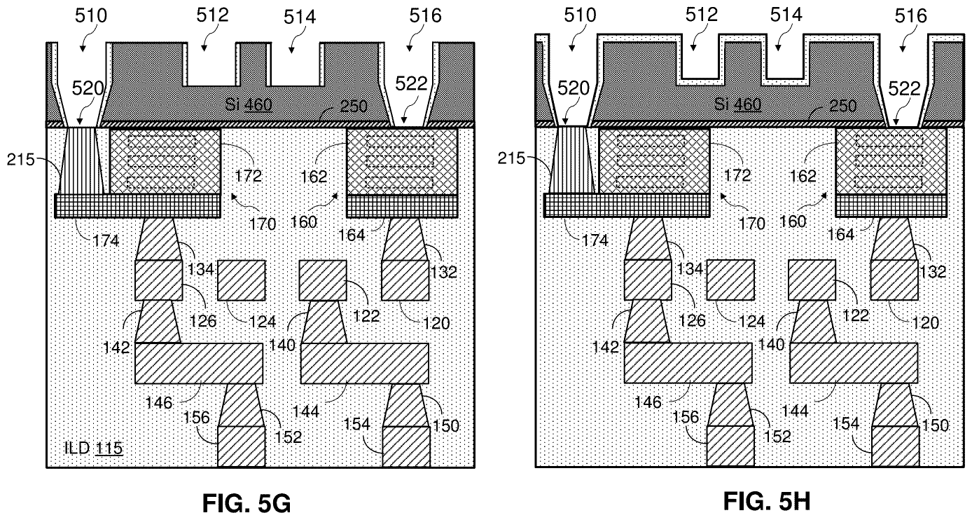

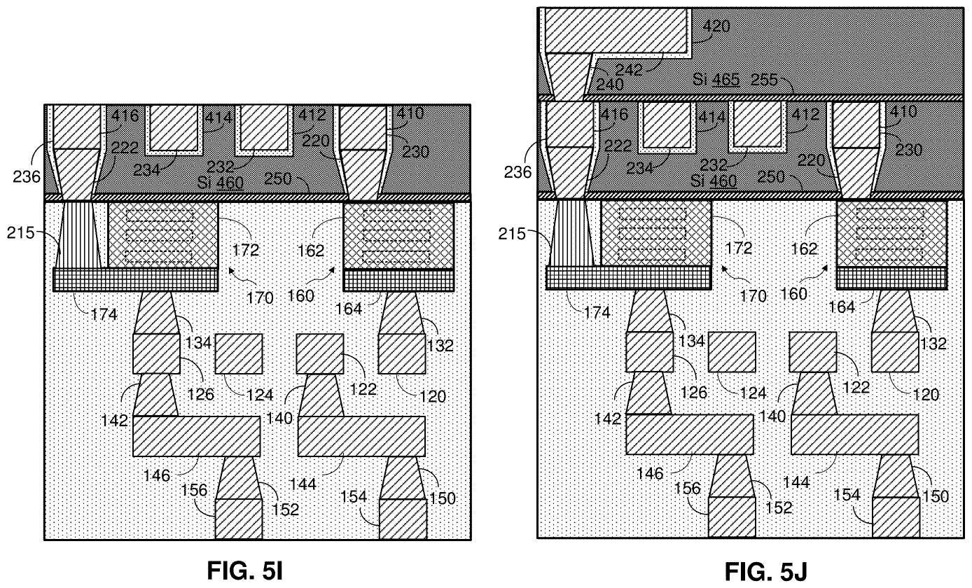

FIGS. 5A to 5I illustrate an exemplary backside process for forming the backside layers 210 including the backside silicon layers 460 and 465 according to certain aspects. The exemplary backside process is shown for the example where the active devices 160 and 170 are implemented using the gate-all-around FET process. However, it is to be appreciated that the exemplary backside process is also applicable to the case where the active devices 160 and 170 are implemented using the FinFET process.

FIG. 5A shows an example of the chip 100 after formation of the active devices 160 and 170, the via 215, and the frontside layers 105 during frontside processing. In this example, the active devices 160 and 170 and the frontside layers 105 are fabricated on the silicon substrate 108.

After formation of the active devices 160 and 170 and the frontside layers 105, a carrier substrate may be bonded to the top of the chip 100 for structural support. The chip 100 may then be flipped to expose the backside of the silicon substrate 108, as shown in FIG. 5B. Note that the carrier substrate is not shown in FIG. 5B for ease of illustration.

In FIG. 5C, most or all of the silicon substrate 108 is removed to expose the backside of the active devices 160 and 170. For example, the silicon substrate 108 may be grounded and/or polished off (e.g., using chemical mechanical polishing (CMP)).

In FIG. 5D, the first etch stop layer 250 and the first backside silicon layer 460 are formed on the backside of the chip 100. For example, the first backside silicon layer 460 may be formed by depositing silicon. The first backside silicon layer 460 may include polysilicon and/or epitaxial silicon.

In FIG. 5E, the first backside silicon layer 460 is etched to form trenches 510, 512, 514, and 516 for the vias 220 and 222 and the metal paths 230, 232, 234, and 236 in the metal layer M0 (shown in FIGS. 2A and 2B). The areas of the first backside silicon layer 460 that are etched to form the trenches 510, 512, 514, and 516 may be defined using lithography. In this example, the first etch stop layer 250 acts as an etch stop for the etching process used to etch the first backside silicon layer 460. The first backside silicon layer 460 may be etched using plasma dry etch, reactive-ion etch (RIE), etc.

FIG. 5F shows an example in which a thin electrical barrier layer 518 (e.g., silicon oxide layer) is deposited on the backside of the chip 100.

FIG. 5G shows an example in which portions of the electrical barrier layer 518 on the bottoms of the trenches 510 and 516 are etched away using a directional etching process to expose the underlying etch stop layer 250. The directional etching process may also etch away the remaining electrical barrier layer 518 except for the portions of the electrical barrier layer 518 deposited on the sidewalls of the trenches 510, 512, 514, and 516. Examples of directional etching processes that may be used include plasma dry etch, reactive-ion etch (RIE), etc.

After the directional etching process, the portions of the etch stop layer 250 that are exposed at the bottoms of the trenches 510 and 516 are etched away to create holes 520 and 522 (i.e., openings) through the etch stop layer 250 to expose the backsides of the active devices 160 and 170.

In FIG. 5H, additional electrical barrier material (e.g., silicon oxide) may be deposited on the backside of the chip 100 to restore portions of the electrical barrier layer 518 that were etched away during the direction etching process in FIG. 5G. Before the deposition, a carbon hard mask (CHM) (not shown) or other material may be placed over the holes 520 and 522 to prevent the electrical barrier material from filling the holes 520 and 522 during the deposition. After the deposition, the CHM may be removed.

FIG. 5I illustrates a backside metallization process in which metal is deposited in the trenches 510, 512, 514, and 516 to form the vias 220 and 222 and the metal paths 230, 232, 234, and 236 in the backside metal layer BM0. The metal may include one or more different types of metals.

FIG. 5J shows an example in which the deposition, etching, and metallization processes illustrated in FIGS. 5D to 5I are repeated to form the second backside silicon layer 465, the electrical barrier 420, the via 240, the metal path 242 in the backside metal layer BM1.

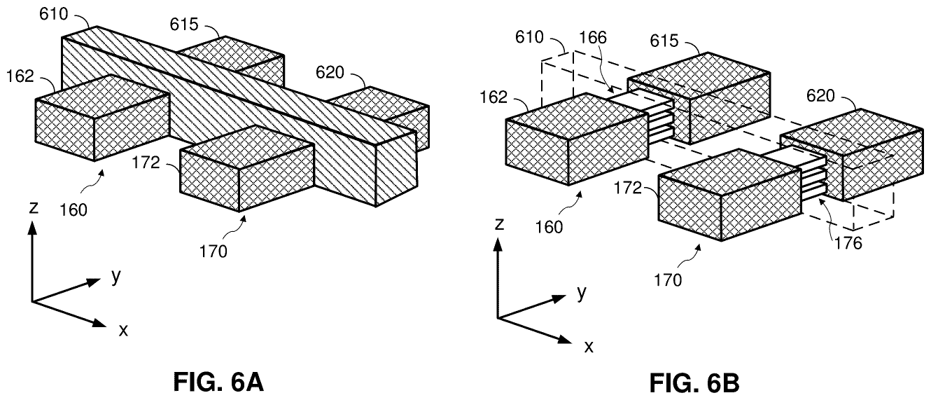

FIG. 6A shows an example of a perspective view of the active devices 160 and 170 according to certain aspects. In this example, the active devices 160 and 170 are implemented using the gate-all-around FET process.

In the example in FIG. 6A, the active device 160 includes the epi layer 162 and the one or more nanosheets 166 discussed above. The active device 160 also includes a gate 610 and another epi layer 615. In this example, the gate 610 is disposed between the epi layers 162 and 615. The one or more nanosheets 166 are coupled between the epi layers 162 and 615 and pass through the gate 610 to provide the one or more channels of the active device 160. FIG. 6B shows the gate 610 in phantom to show the one or more nanosheets 166 passing through the gate 610. In this example, the epi layer 162 corresponds to a first source/drain of the active device 160 and the epi layer 615 corresponds to a second source/drain of the active device 160.

In the example in FIG. 6A, the active device 170 includes the epi layer 172 and the one or more nanosheets 176 discussed above. The active device 170 also includes the gate 610 and another epi layer 620. In this example, the gate 610 is disposed between the epi layers 172 and 620. The one or more nanosheets 176 are coupled between the epi layers 172 and 620 and pass through the gate 610 to provide the one or more channels of the active device 170. FIG. 6B shows the gate 610 in phantom to show the one or more nanosheets 176 passing through the gate 610. In this example, the epi layer 172 corresponds to a first source/drain of the active device 170 and the epi layer 620 corresponds to a second source/drain of the active device 170.

In the example shown in FIG. 6A, the active devices 160 and 170 share the gate 610. However, it is to be appreciated that, in other implementations, the gate 610 may be cut between the active devices 160 and 170 to provide the active devices 160 and 170 with separate gates.

It is to be appreciated that, in some implementations, the backside via 220 may be coupled to the epi layer 162 of the active device 160 and the frontside via 132 may be coupled to the epi layer 615 of the active device 160, or vice versa. It is also to be appreciated that, in some implementations, the backside via 222 may be coupled to the epi layer 172 of the active device 170 and the frontside via 134 may be coupled to the epi layer 620 of the active device 170, or vice versa.

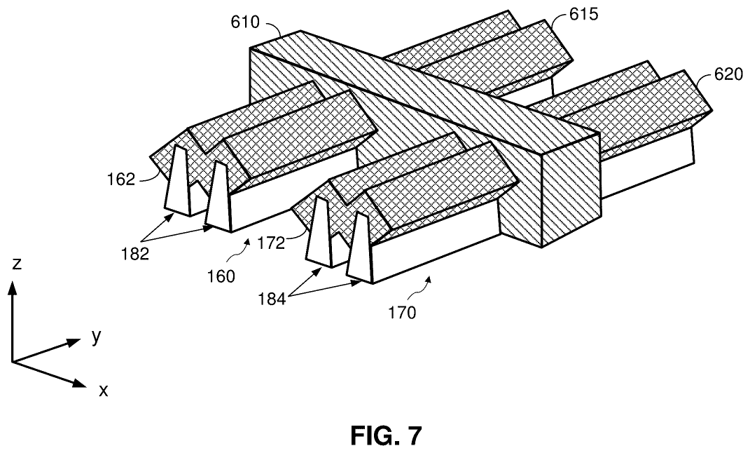

FIG. 7 shows another example of a perspective view of the active devices 160 and 170 according to certain aspects. In this example, the active devices 160 and 170 are implemented using the FinFET process.

In the example in FIG. 7, the active device 160 includes the epi layers 162 and 615, the gate 610, and the one or more fins 182 discussed above. In this example, the one or more fins 182 pass through the gate 610 to provide the one or more channels of the active device 160. The epi layer 162 is disposed on a first portion of the one or more fins 182, the epi layer 615 is disposed on a second portion of the one or more fins 182, and the gate 610 is disposed between the epi layers 162 and 615.

In the example in FIG. 7, the active device 170 includes the epi layers 172 and 620, the gate 610, and the one or more fins 184 discussed above. In this example, the one or more fins 184 pass through the gate 610 to provide the one or more channels of the active device 170. The epi layer 172 is disposed on a first portion of the one or more fins 184, the epi layer 620 is disposed on a second portion of the one or more fins 184, and the gate 610 is disposed between the epi layers 172 and 620.

In the example shown in FIG. 7, the active devices 160 and 170 share the gate 610. However, it is to be appreciated that, in other implementations, the gate 610 may be cut between the active devices 160 and 170 to provide the active devices 160 and 170 with separate gates.

It is to be appreciated that, in some implementations, the backside via 220 may be coupled to the epi layer 162 of the active device 160 and the frontside via 132 may be coupled to the epi layer 615 of the active device 160, or vice versa. It is also to be appreciated that, in some implementations, the backside via 222 may be coupled to the epi layer 172 of the active device 170 and the frontside via 134 may be coupled to the epi layer 620 of the active device 170, or vice versa.

In the examples discussed above, each of the active devices 160 and 170 includes one or more nanosheets or one or more fins to provide one or more channels. However, it is to be appreciated that the active devices 160 and 170 are not limited to these examples and that other types of channels may be used. As used herein, a “channel” is a structure that conducts current between a first source/drain and a second source/drain of an active device (e.g., a transistor).

Implementation examples are described in the following numbered clauses:

1. A chip, comprising:
an active device;
a first backside silicon layer disposed below the active device;
a first backside metal path electrically coupled to the active device and extending through the first backside silicon layer; and
a first electrical barrier disposed between one or more sides of the first backside metal path and the first backside silicon layer.

2. The chip of clause 1, wherein the first electrical barrier comprises silicon oxide.

3. The chip of clause 1, wherein the first electrical barrier comprises tantalum nitride.

4. The chip of any one of clauses 1 to 3, wherein the first backside silicon layer comprises polysilicon.

5. The chip of any one of clauses 1 to 3, wherein the first backside silicon layer comprises epitaxial silicon.

6. The chip of any one of clauses 1 to 5, wherein the active device comprises:
a gate; and
one or more nanosheets passing through the gate, wherein the first backside metal path is electrically coupled to the one or more nanosheets.

7. The chip of any one of clauses 1 to 5, wherein the active device comprises:
a gate; and
one or more fins passing through the gate, wherein the first backside metal path is electrically coupled to the one or more fins.

8. The chip of any one of clauses 1 to 7, wherein the first backside metal path is part of a backside power distribution network configured to provide the active device with a supply voltage.

9. The chip of any one of clauses 1 to 8, further comprising:
a second backside silicon layer disposed below the first backside silicon layer;
a second backside metal path electrically coupled to the first backside metal path and extending through the second backside silicon layer; and
a second electrical barrier disposed between one or more sides of the second backside metal path and the second backside silicon layer.

10. The chip of clause 9, wherein each of the first electrical barrier and the second electrical barrier comprises silicon oxide.

11. The chip of clause 9, wherein each of the first electrical barrier and the second electrical barrier comprises tantalum nitride.

12. The chip of any one of clauses 9 to 11, wherein the first backside metal path and the second backside metal path are part of a backside power distribution network configured to provide the active device with a supply voltage.

13. The chip of any one of clauses 1 to 12, further comprising frontside signal routing electrically coupled to the active device.

14. The chip of clause 13, wherein the first backside metal path is electrically coupled to a first source/drain of the active device and the frontside signal routing is electrically coupled to a second source/drain of the active device.

15. The chip of clause 14, wherein the active device includes a gate and one or more channels passing through the gate and electrically coupled between the first source/drain and the second source/drain.

16. A chip, comprising:
active devices;
one or more backside silicon layers disposed below the active devices; and
a backside power distribution network extending through the one or more backside silicon layers, wherein the backside power distribution network is configured to provide the active devices with a supply voltage.

17. The chip of clause 16, further comprises one or more electrical barriers between the backside power distribution network and the one or more backside silicon layers.

18. The chip of clause 17, wherein the one or more electrical barriers comprise silicon oxide.

19. The chip of clause 17, wherein the one or more electrical barriers comprise tantalum nitride.

20. The chip of any one of clauses 16 to 19, further comprising:
a frontside dielectric layer disposed above the active devices; and
frontside metal signal routing coupled to one or more of the active devices and extending through the frontside dielectric layer.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures. As used herein, the term “approximately” means within 90 percent to 110 percent of the stated value.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element. At least one of A, B, and C means A, B, C, AB, BC, AC, or ABC.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A chip, comprising:
an active device;
a first backside silicon layer disposed below the active device;
a first backside metal path electrically coupled to the active device and extending through the first backside silicon layer; and
a first electrical barrier disposed between one or more sides of the first backside metal path and the first backside silicon layer.

2. The chip of claim 1, wherein the first electrical barrier comprises silicon oxide.

3. The chip of claim 1, wherein the first electrical barrier comprises tantalum nitride.

4. The chip of claim 1, wherein the first backside silicon layer comprises polysilicon.

5. The chip of claim 1, wherein the first backside silicon layer comprises epitaxial silicon.

6. The chip of claim 1, wherein the active device comprises:
a gate; and
one or more nanosheets passing through the gate, wherein the first backside metal path is electrically coupled to the one or more nanosheets.

7. The chip of claim 1, wherein the active device comprises:
a gate; and
one or more fins passing through the gate, wherein the first backside metal path is electrically coupled to the one or more fins.

8. The chip of claim 1, wherein the first backside metal path is part of a backside power distribution network configured to provide the active device with a supply voltage.

9. The chip of claim 1, further comprising:
a second backside silicon layer disposed below the first backside silicon layer;
a second backside metal path electrically coupled to the first backside metal path and extending through the second backside silicon layer; and
a second electrical barrier disposed between one or more sides of the second backside metal path and the second backside silicon layer.

10. The chip of claim 9, wherein each of the first electrical barrier and the second electrical barrier comprises silicon oxide.

11. The chip of claim 9, wherein each of the first electrical barrier and the second electrical barrier comprises tantalum nitride.

12. The chip of claim 9, wherein the first backside metal path and the second backside metal path are part of a backside power distribution network configured to provide the active device with a supply voltage.

13. The chip of claim 1, further comprising frontside signal routing electrically coupled to the active device.

14. The chip of claim 13, wherein the first backside metal path is electrically coupled to a first source/drain of the active device and the frontside signal routing is electrically coupled to a second source/drain of the active device.

15. The chip of claim 14, wherein the active device includes a gate and one or more channels passing through the gate and electrically coupled between the first source/drain and the second source/drain.

16. A chip, comprising:
active devices;
one or more backside silicon layers disposed below the active devices; and
a backside power distribution network extending through the one or more backside silicon layers, wherein the backside power distribution network is configured to provide the active devices with a supply voltage.

17. The chip of claim 16, further comprises one or more electrical barriers between the backside power distribution network and the one or more backside silicon layers.

18. The chip of claim 17, wherein the one or more electrical barriers comprise silicon oxide.

19. The chip of claim 17, wherein the one or more electrical barriers comprise tantalum nitride.

20. The chip of claim 16, further comprising:
a frontside dielectric layer disposed above the active devices; and
frontside metal signal routing coupled to one or more of the active devices and extending through the frontside dielectric layer.
